(19) United States
(12) Patent Application Publication
(10) Pub. No.: US 2019/0067397 A1
(43) Pub. Date: Feb. 28, 2019

(54) DISPLAY PANEL AND METHOD FOR MANUFACTURING THE SAME

(71) Applicants: HKC Corporation Limited, Shenzhen City, Guangdong (CN); Chongqing HKC Optoelectronics Technology Co., Ltd., Chongqing (CN)

(72) Inventors: En-Tsung CHO, Chongqing (CN); Yiqun TIAN, Chongqing (CN); Fengyun YANG, Chongqing (CN); Kun FAN, Chongqing (CN)

(21) Appl. No.: 15/740,770

(22) PCT Filed: Oct. 20, 2017
(86) PCT No.: PCT/CN2017/107023

§ 371 Date: Dec. 28, 2017

(30) Foreign Application Priority Data
Aug. 28, 2017 (CN) 201710750904.X

(51) Int. Cl. H01L 27/32; H01L 51/56

(52) U.S. Cl. CPC H01L 27/3258; H01L 27/322; H01L 27/1248; H01L 27/3262; H01L 51/56; H01L 27/3246

(57) ABSTRACT

A display panel comprises a substrate, a plurality of thin film transistors arranged on the substrate, a passivation layer disposed on the substrate and covering the plurality of thin film transistors, a pixel definition layer disposed on the passivation layer and configured to enable a plurality of light emitting elements to be disposed therein, a planarization layer disposed between the passivation layer and the pixel definition layer and having a groove structure, a color filter layer disposed between the passivation layer and the planarization layer and corresponding to the location of the groove structure, and a transparent electrode layer disposed on the planarization layer and covering the groove structure. Wherein the plurality of light emitting elements are disposed in the groove structure of the planarization layer and is aligned to the location of the color filter layer.

### FIELD OF THE INVENTION

The present disclosure relates to a display panel and a method for manufacturing the same, and more particularly to an organic light-emitting diode display and a method for manufacturing the same.

### BACKGROUND OF THE INVENTION

At present, the high resolution pixel flat display panel is a trend of the market, especially an active matrix organic light emitting diode (AMOLED) display panel is gaining interest and the AMOLED panel of a screen size of middle or small type with pixel density 200 ppi occupies a dominant position in the electronic display market. Also, an AMOLED with a wide video graphics array (WVGA) has gained popularity because of its resolution ratio higher than the VGA resolution ratio of 800*480 or about 200 ppi, and in the near future the developing trend of the display panel is toward to a higher resolution such as 250 ppi, 300 ppi and 350 ppi.

The existing technology used to define the resolution in the fabrication is mainly through the Side by Side technology, however, the technology has certain difficulty in the production of 300 ppi and more than 300 ppi products. Therefore, another implementation mode is adopted by the industry for manufacturing the AMOLED panel, that is, a WOLED (White Organic Light Emitting Diode) coupled with the color filter layer. Besides, because of the WOLED can be fabricated by a fully open metal shield during the process of forming a layer containing an organic compound (strictly speaking, light emitting layer), therefore an opening ratio in a pixel is to be improved and it is possible to achieve high quality resolution.

The self-luminous display panel has the characteristics of high contrast ratio, wide color gamut, high response speed and the like. Since the backlight module does not need to be used, the self-luminous display panel can be made thinner and even flexible compared with a liquid crystal display panel. The illustrations of the self-luminous display panel is mainly controlled by a specific active array switch to adjust the switching and brightness of the light emitting elements of the panel, and then the screen is displayed after adjusting the proportion of the three primary colors.

A metal oxide semiconductor is usually adopted for the composition of the active array switch using for controlling the self-luminous display panel not only because of its open-state current in higher and off-state current in lower but also the characteristics of high uniformity and high stability. The structures of the active array switch commonly used are Etch Stop Layer (ESL), Back Channel Etch (BCE), Co-planner Self-Align Top Gate and Dual Gate. Further, for the process of fabricating the Co-planner Self-Align Top Gate structure it is no need to consider the problem regarding etching channel and it is gaining interest as reducing the length of the gate channel and therefore raising the resolution of the display panel. Meanwhile, But in order to eliminate the electronic channel from the influence of light ray there are usually disposed with a shielding layer on the electronic channel.

The method for manufacturing a self-luminous display panel such as Organic Electro-Luminescent Display (OLED) generally comprises the processes of applying depositing, photolithographic, and etching processes to form an interlayer insulation layer, a plurality of source/drain terminals, a planarization layer, an anode, a pixel definition layer, and other relevant layer depending on the requirements on the gate insulation layer, in sequence.

Such conventional method has a lot of the processes and the procedures are complex, in addition, since the one function of the planarization layer is used to support the pixel definition layer therefore once the relevant procedures for making the pixel definition layer are omitted, the displaying of the self-luminous display panel will be abnormal or color mixture and the illustrating performance is influenced.

### SUMMARY OF THE INVENTION

In order to solve the above technical problems, it is an object of the present invention to provide a display panel and a method for manufacturing the same, by thinning the planarization layer corresponding to the light emitting region to raise the light emitting efficiency of the self-luminous display panel and to optimize the process and the yield of the panel, thereby the color shifted phenomenon of the self-luminous display panel is reduced.

The purpose of the present invention and the aforementioned technical problem to be solved can be realized by the following technical embodiments.

The present disclosure provides a display panel comprising a substrate, a plurality of thin film transistors arranged on the substrate, a passivation layer disposed on the substrate and covering the plurality of thin film transistors, a pixel definition layer disposed on the passivation layer and configured to enable a plurality of light emitting elements to be disposed therein, a planarization layer disposed between the passivation layer and the pixel definition layer and having a groove structure, a color filter layer disposed between the passivation layer and the planarization layer and corresponding to the location of the groove structure, and a transparent electrode layer disposed on the planarization layer and covering the groove structure. Wherein the plurality of light emitting elements are disposed in the groove structure of the planarization layer and is aligned to the location of the color filter layer.

In one embodiment of the present invention, a projection of the groove structure onto the substrate is included in a projection of the color filter layer onto the substrate.

In one embodiment of the present invention, the color filter layer includes a plurality of t color resistors configured in an array, and colors of any adjacent color resistors are different.

In one embodiment of the present invention, each of the plurality of light emitting elements is a white light emitting diode.

In one embodiment of the present invention, each of the plurality of light emitting elements is a colored light emitting diode.

In one embodiment of the present invention, each of the plurality of thin film transistors comprises a semiconductor layer, a source electrode, a drain electrode and a gate electrode. In the meanwhile, the gate electrode is interposed between an interlayer dielectric layer, and a gate insulating layer is disposed between the drain electrode and the semiconductor layer.

In one embodiment of the present invention, the source electrode and the drain electrode are composed of a titanium material, a tantalum material or a group of titanium, tantalum and an alloy compound thereof.

In one embodiment of the present invention, the semiconductor layer is an indium gallium zinc oxide thin film layer.

The purpose of the present invention and the aforementioned technical problem to be solved can be further realized by the following technical embodiments.

Another object of the present invention is to provide a method of manufacturing a display panel comprising providing a substrate; forming a plurality of thin film transistors on the substrate; forming a passivation layer over the substrate and covering the plurality of thin film transistors; forming a planarization layer having a groove structure over the passivation layer by employing a mask; forming a color filter layer over the substrate and interposed between the passivation layer and the planarization layer and aligned to the location of the groove structure; forming a transparent electrode layer over the planarization layer and covering the groove structure; and forming a pixel definition layer over the planarization layer and configured to enable a plurality of light emitting elements to be disposed therein. Wherein the plurality of light emitting elements are disposed in the groove structure of the planarization layer and are aligned to the location of the color filter layer. Moreover, the pixel definition layer is connected with the plurality of thin film transistors through the transparent electrode layer.

In one embodiment of the present invention, the mask is a half tone mask or a gray scale mask.

In one embodiment of the present invention, the planarization layer is etched by employing the half tone mask or the gray scale mask so as to form the groove structure corresponding to the location of the color filter layer.

In one embodiment of the present invention, a projection of the groove structure onto the substrate is included in a projection of the color filter layer onto the substrate.

In one embodiment of the present invention, the color filter layer includes a plurality of color resistors configured in an array, and colors of any adjacent color resistors are different.

In one embodiment of the present invention, each of the plurality of thin film transistors comprises a semiconductor layer, a source electrode, a drain electrode and a gate electrode. Furthermore, a gate insulating layer is interposed between the drain electrode and the semiconductor layer.

In one embodiment of the present invention, the semiconductor layer is an indium gallium zinc oxide thin film layer.

In one embodiment of the present invention, the height of an area of the planarization layer locating with corresponding to the position between the groove structure and the color filter layer is equal to or not equal to other region of the planarization layer.

Another object of the present invention is to provide a display panel comprising a substrate, a plurality of thin film transistors arranged on the substrate, a pixel definition layer disposed on the passivation layer and configured to enable a plurality of light emitting elements to be disposed therein, a planarization layer interposed between the passivation layer and the pixel definition layer and having a groove structure, a color filter layer interposed between the passivation layer and the planarization layer and aligned to the location of the groove structure of the planarization layer, and a transparent electrode layer disposed on the planarization layer and covering the groove structure.

In the meanwhile, the plurality of light emitting elements are disposed in the groove structure of the planarization layer and is aligned to the location of the color filter layer, and the color filter layer includes a plurality of color resistors configured in an array, and moreover, colors of any adjacent color resistors are different. In addition, the plurality of light emitting elements are aligned to the location of the color filter layer, and each of the plurality of light emitting elements is a white light emitting diode or a colored light emitting diode. Furthermore, a projection of the groove structure onto the substrate is included in a projection of the color filter layer onto the substrate.

The self-luminous display panel of the present invention employs the method of thinning the planarization layer corresponding to the light emitting region, it may raise the light emitting efficiency and optimize the process and the yield of the panel, and thereby the color shifted phenomenon of the self-luminous display panel is reduced.

Various other objects, advantages and features of the present invention will become readily apparent from the ensuing detailed description, and the novel features will be particularly pointed out in the appended claims.

### BRIEF DESCRIPTION OF FIGURES

The following detailed descriptions, given by way of example, and not intended to limit the present invention solely thereto, will be best be understood in conjunction with the accompanying figures:

FIG. 1 is a schematic cross-sectional view of an exemplary display panel according to an embodiment of the present invention;

FIG. 2 is a cross-sectional schematic view of a display panel according to an embodiment of the present invention;

FIG. 3 is a schematic cross-sectional view of a light-emitting element of a display panel according to an embodiment of the present invention;

FIG. 4 is a cross-sectional schematic view of a display panel according to another embodiment of the present invention; and

FIG. 5 is a schematic cross-sectional view of a light-emitting element of a display panel according to another embodiment of the present invention.

### DETAILED DESCRIPTION OF THE EMBODIMENTS

The following embodiments are referring to the accompanying drawings for exemplifying specific implementable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

The drawings and description are to be regarded as illustrative in nature and not restrictive. Like reference numerals designate like elements throughout the specification. In addition, the size and thickness of each component shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thicknesses of some layers and areas are exaggerated. It will be understood that, when an element such as a layer, film, region, or substrate is referred to as being “on” another element, it can be directly on the other element or intervening elements may also be present.

Furthermore, in the specification, “on” implies being positioned above or below a target element and does not imply being necessarily positioned on the top on the basis of a gravity direction.

For further explaining the technical means and efficacy of the present application intended to file, a display panel and a method for manufacturing the same including the embodiments, structures, features and effects thereof according to the present invention will be apparent from the following detailed description and accompanying drawings.

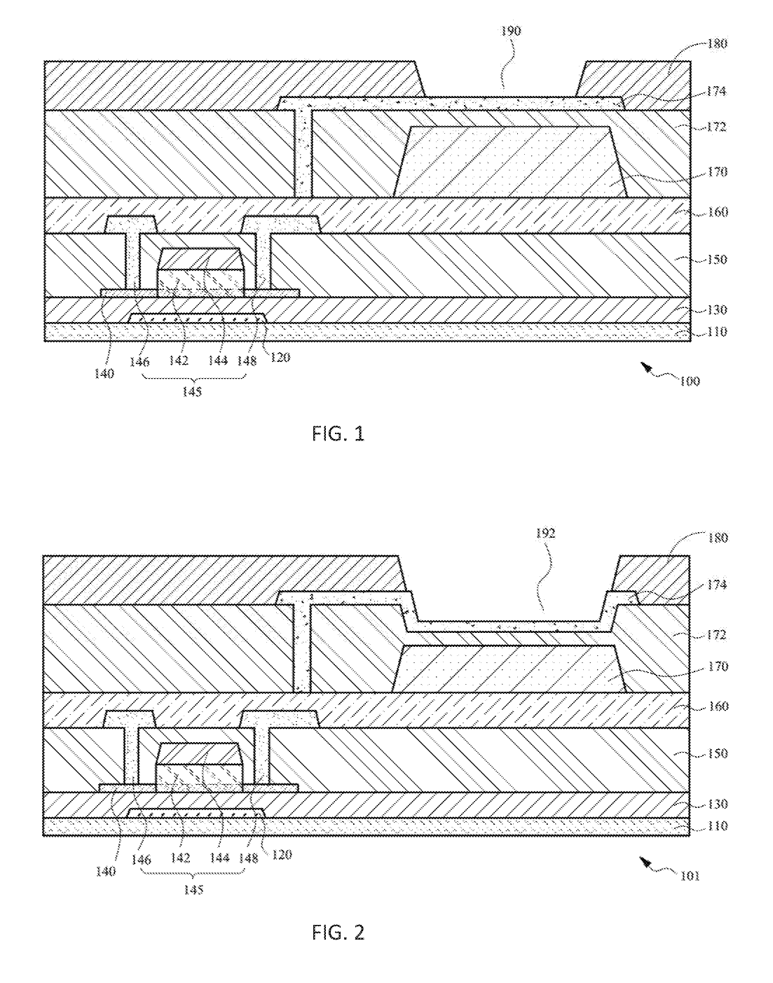

FIG. 1 is a schematic cross-sectional view of an exemplary display panel according to an embodiment of the present invention. Referring to FIG. 1, a display panel 100 comprises a substrate 110, a light shielding layer 120 formed on the substrate 110, a buffer layer 130 formed on the substrate 110 and covering the light shielding layer 120, a semiconductor layer 140 formed on the buffer layer 130, and a plurality of thin film transistors 145 formed on the buffer layer 130. In the meanwhile, each of the plurality of thin film transistors comprises a semiconductor layer, a source electrode 148, a drain electrode 146, a gate electrode 144 configured for connecting with the source electrode 148 on the source region and the drain electrode 146 on the drain region respectively, and a gate insulating layer 142 disposed between the drain electrode 146 and the semiconductor layer.

Moreover, an interlayer dielectric layer 150 is formed on the buffer layer 130 and covering the gate electrode 144 and a source layer corresponding to locations of the source electrode 148 and the drain electrode 146. A passivation layer 160 is formed on the interlayer dielectric layer 150, and covering the source electrode 148 on the source region and the drain electrode 146 on the drain region. A color filter layer 170 is formed on the passivation layer, and a planarization layer 172 is formed on the passivation layer 160 and covering the color filter layer 170.

Furthermore, a transparent electrode layer 174 is formed on the planarization layer 172 and covering the passivation layer 160, and a pixel definition layer 180 is formed on the transparent electrode layer 174 and covering the planarization layer 172. Besides, the pixel definition layer 180 has a groove structure capable of enabling a plurality of light emitting elements 190 to be disposed therein.

The above mentioned process comprises much fabrication procedures and if looking forward to reduce the procedure, there is lower possibility to withdraw the procedures of producing the pixel definition layer due to concern of displaying abnormal and color mixture may occurred and the illustrating performance is influenced. Moreover, due to the penetrate elastic of the planarization layer 172 is easy influenced by the temperature or heat treatment, after completing the planarization layer 172 the less subsequent process is preferable. Therefore, the present invention provides a new technical solution which can effectively reduce the subsequent process and improve the displaying quality of the display panel.

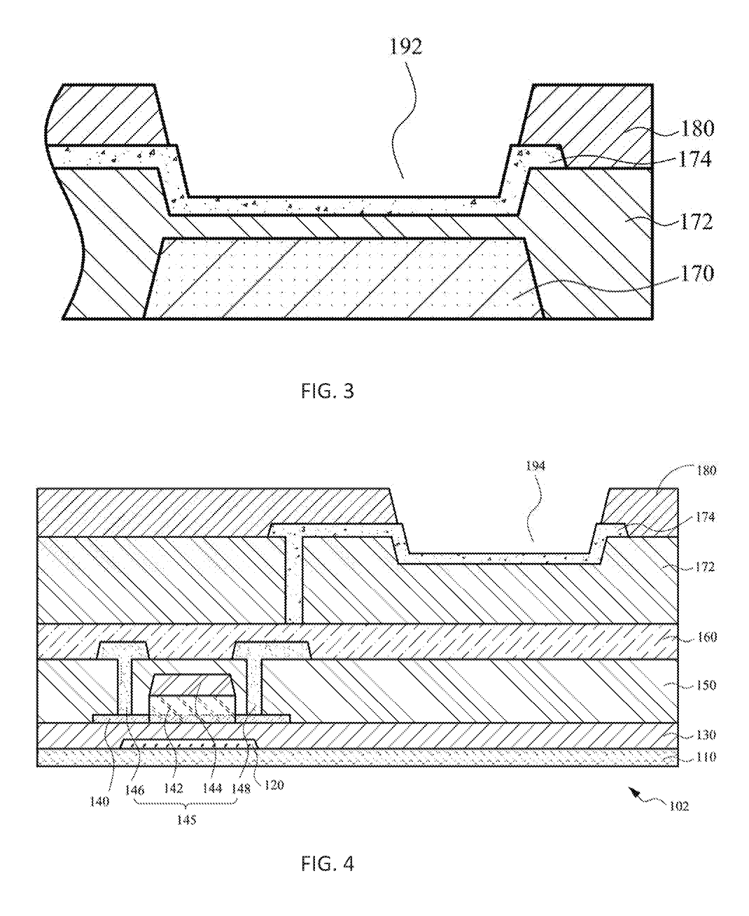

FIG. 2 is a cross-sectional schematic view of a display panel according to an embodiment of the present invention, and FIG. 3 is a schematic cross-sectional view of a light-emitting element of a display panel according to an embodiment of the present invention. Referring to FIGS. 2 and 3, in one embodiment of the present invention, a display panel 101 comprises a substrate 110, a plurality of thin film transistors 145 arranged on the substrate 110, a passivation layer 160 disposed on the substrate 110 and covering the plurality of thin film transistors 145, a pixel definition layer 180 disposed on the plurality of thin film transistors 145 and configured to enable a plurality of light emitting elements 192 to be disposed therein, a planarization layer 172 disposed between the plurality of thin film transistors 145 and the pixel definition layer 180 and having a groove structure, a color filter layer 170 disposed on the substrate 110 and interposed between the passivation layer 160 and the planarization layer 172 and corresponding to the location of the groove structure, and a transparent electrode layer 174 disposed on the planarization layer 172 and covering the groove structure. Wherein the plurality of light emitting elements 192 are disposed in the groove structure of the planarization layer 172 and is aligned to the location of the color filter layer 170, as shown in FIG. 3.

In one embodiment of the present invention, the color filter layer 170 includes a plurality of color resistors configured in an array, and colors of any adjacent color resistors are different.

In one embodiment of the present invention, further comprising a buffer layer 130 disposed on the substrate 110 and an interlayer dielectric layer 150 interposed between the buffer layer 130 and passivation layer 160.

In one embodiment of the present invention, the pixel definition layer 180 is connected with the plurality of thin film transistors 145 through the transparent electrode layer 174.

In one embodiment of the present invention, each of the plurality of light emitting elements 192 is a white light emitting diode 192.

In one embodiment of the present invention, the height of an area of the planarization layer 172 located corresponding to the position between the groove structure and the color filter layer 170 is equal to, partial equal to, or not equal to other region of the planarization layer. In particular, the height or the thickness of the planarization layer 172 aligning with the position of the groove structure can be correspondingly adjusted according to requirements.

For example, if the blue light source of the display panel is prone to dimmed, the color filter layer 170 below the corresponding groove structure is a blue colored layer, then the thickness of the planarization layer 172 interposed between the aforementioned groove structure and the blue colored layer is thinner, thereby the light transmittance of the blue colored layer is increased and therefore the blue light source prone to dark is possible further compensated. If the light sources with other colors are liable to dark, the light transmittance can be made up by such similar way.

In one embodiment of the present invention, a projection of the groove structure onto the substrate 110 is included in a projection of the color filter layer 170 onto the substrate 110. This design can ensure that the light emitted by the light emitting elements 192 through the groove structure is totally irradiated on the color filter layer 170, so that the possibility of light leakage can be avoided.

In one embodiment of the present invention, each of the plurality of thin film transistors 145 comprises a semiconductor layer 140, a source electrode 148 and a drain electrode 146. Wherein the semiconductor layer 140 is interposed between the buffer layer 130 and the interlayer dielectric layer 150, one end of the source electrode 148 and one end of the drain electrode 146 are interposed between the passivation layer 160 and the interlayer dielectric layer 150, and the other end of the source electrode 148 and the other end of the drain electrode 146 are connected to the two ends of the semiconductor layer 140 respectively through the interlayer dielectric layer 150.

In one embodiment of the present invention, each of the plurality of thin film transistors 145 also comprises a gate electrode 144 interposed within the interlayer dielectric layer 150, and further comprises a gate insulating layer 142 disposed between the drain electrode 144 and the semiconductor layer 140.

In one embodiment of the present invention, the display panel 101 further comprises a light shielding layer 120 formed on the substrate 110, and a buffer layer 130 covering the light shielding layer 120. The light shielding layer 120 is used to amend the light emitting from the light emitting elements 192 and throughout the color filter layer 170, so as to shield the uneven displaying in the border of the pixel definition layer 180 and therefore the color mixture or uneven displaying of the display panel 101 can be avoided.

In one embodiment of the present invention, the semiconductor layer is an indium gallium zinc oxide thin film layer, for example.

In one embodiment of the present invention, the source electrode 148 and the drain electrode 146 are composed of a titanium material, a tantalum material or a group of titanium, tantalum and an alloy compound thereof.

In one embodiment of the present invention, the groove structure is designed to reduce the thickness of the planarization layer 172 corresponding to the areas locating with the plurality of light emitting elements, therefore the plurality of light emitting elements are more closed to the color filter layer 170.

In another consideration, the penetrate elastic of the planarization layer 172 may be declined after subsequent processes, thereby the yield of the process in fabricating the display panel is easy influenced. Once a display panel implies such design, when the voltage is applied to the display panel 101, the transmittance efficiency of the white light emitting diode 192 can be effectively improved and therefore to improve the displaying quality of the display panel. Furthermore, the influence of the yield of the process can be effectively limited.

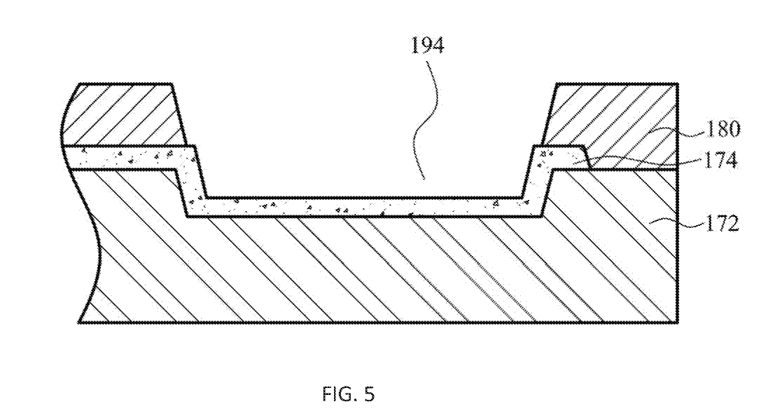

FIG. 4 is a cross-sectional schematic view of a display panel according to another embodiment of the present invention, and FIG. 5 is a schematic cross-sectional view of a light-emitting element of a display panel according to another embodiment of the present invention.

Referring to FIGS. 4 and 5, in one embodiment of the present invention, a display panel 102 comprises a substrate 110, a plurality of thin film transistors 145 arranged on the substrate 110, a passivation layer 160 disposed on the substrate 110 and covering the plurality of thin film transistors 145, a pixel definition layer 180 disposed on the passivation layer 160 and configured to enable a plurality of light emitting elements 192 to be disposed therein, a planarization layer 172 disposed between the passivation layer 160 and the pixel definition layer 180 and having a groove structure, and a transparent electrode layer 174 disposed on the planarization layer 172 and covering the groove structure. Wherein the plurality of light emitting elements 192 are colored light emitting diodes 194 and disposed in the groove structure of the planarization layer 172, as shown in FIG. 5.

The display panel 102 is compared to the display panel 101 in the above embodiment, the light emitting element is a colored light emitting diode 194. Thus, the display panel 102 can save the process for producing the colored resist layer 170 and optimize the process of fabricating the display panel. In addition, in order to improve the displaying performance of the display panel, the flat layer 172 designing with groove structure is being introduced. Therefore, when the voltage is applied to the display panel 101, the transmittance efficiency of the colored light emitting diode 194 can be effectively improved.

Referring to FIGS. 2, 3, 4 and 5, in one embodiment of the present invention, a method of manufacturing a display panel (101,102) comprises: providing a substrate 100; forming a plurality of thin film transistors 145 on the substrate 100; forming a passivation layer 160 over the substrate 110 and covering the plurality of thin film transistors 145; forming a planarization layer 172 having a groove structure over the passivation layer 160 by employing a mask; forming a color filter layer 170 over the substrate and interposed between the passivation layer 160 and the planarization layer 172 and aligned to the location of the groove structure; forming a transparent electrode layer 174 over the planarization layer 172 and covering the groove structure; and forming a pixel definition layer 180 over the passivation layer 160 and configured to enable a plurality of light emitting elements to be disposed therein.

Wherein the plurality of light emitting elements (192, 194) are disposed in the groove structure of the planarization layer and are aligned to the location of the color filter layer. Moreover, the pixel definition layer 180 is connected with the plurality of thin film transistors 145 through the transparent electrode layer 174.

In one embodiment of the present invention, the mask is a half tone mask or a gray scale mask. Meanwhile, the planarization layer 172 is etched by employing the half tone mask or the gray scale mask so as to form the groove structure corresponding to the location of the color filter layer 170.

In one embodiment of the present invention, the height of an area of the planarization layer 172 locating with corresponding to the position of the groove structure is equal to, partial equal to, or not equal to other region of the planarization layer.

In one embodiment of the present invention, the light emitting element 192, 194 may be, for example, a white light emitting diode 192 or a colored light emitting diode 194, of cause it also may be a mixture of the white light emitting diode 192 and the colored light emitting diode 194 according to the design or requirements.

In some embodiments, the display panel may include, for example, organic light emitting diodes (OLEDs), White Organic Light Emitting Diode (W-OLED), Active matrix Organic Light Emitting Diodes (AMOLED), Passive matrix Organic Light Emitting Diodes (PMOLED), but not limited thereto.

The self-luminous display panel of the present invention employs the method of thinning the planarization layer corresponding to the light emitting region, it may raise the light emitting efficiency and optimize the process and the yield of the panel, and thereby the color shifted phenomenon of the self-luminous display panel is reduced.

In addition, in the specification, unless explicitly described to the contrary, the word “comprise” and variations such as “comprises” or “comprising” will be understood to imply the inclusion of stated elements but not the exclusion of any other elements.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A display panel, comprising:
a substrate;
a plurality of thin film transistors, arranged on the substrate;
a passivation layer, disposed on the substrate and covering the plurality of thin film transistors;
a pixel definition layer, disposed on the passivation layer and configured to enable a plurality of light emitting elements to be disposed therein;
a planarization layer, disposed between the passivation layer and the pixel definition layer and having a groove structure;
a color filter layer, disposed between the passivation layer and the planarization layer and corresponding to a location of the groove structure; and
a transparent electrode layer, disposed on the planarization layer and covering the groove structure;
wherein the plurality of light emitting elements are disposed in the groove structure of the planarization layer and aligned to the location of the color filter layer.

2. The display panel according to claim 1, wherein a projection of the groove structure onto the substrate is included in a projection of the color filter layer onto the substrate.

3. The display panel according to claim 1, wherein the color filter layer comprises a plurality of color resistors configured in an array, and colors of any adjacent color resistors are different.

4. The display panel according to claim 1, wherein each of the plurality of light emitting elements is a white light emitting diode.

5. The display panel according to claim 1, wherein each of the plurality of light emitting elements is a colored light emitting diode.

6. The display panel according to claim 1, wherein each of the plurality of thin film transistors comprises a semiconductor layer, a source electrode, a drain electrode and a gate electrode.

7. The display panel according to claim 6, further comprising a gate insulating layer disposed between the drain electrode and the semiconductor layer.

8. The display panel according to claim 6, wherein the source electrode and the drain electrode are composed of a titanium material, a tantalum material or a group of titanium, tantalum and an alloy compound thereof.

9. The display panel according to claim 6, wherein the semiconductor layer is an indium gallium zinc oxide thin film layer.

10. A method of manufacturing a display panel, comprising steps of:
providing a substrate;
forming a plurality of thin film transistors on the substrate;
forming a passivation layer over the substrate and covering the plurality of thin film transistors;
forming a planarization layer having a groove structure over the passivation layer by employing a mask;
forming a color filter layer over the substrate and interposed between the passivation layer and the planarization layer and aligned to a location of the groove structure;
forming a transparent electrode layer over the planarization layer and covering the groove structure; and
forming a pixel definition layer over the planarization layer and configured to enable a plurality of light emitting elements to be disposed therein;
wherein the plurality of light emitting elements are disposed in the groove structure of the planarization layer and are aligned to the location of the color filter layer;
wherein the pixel definition layer is connected with the plurality of thin film transistors through the transparent electrode layer.

11. The method of manufacturing a display panel according to claim 10, wherein the mask is a half tone mask.

12. The method of manufacturing a display panel according to claim 11, wherein the planarization layer is etched by employing the half tone mask to form the groove structure corresponding to the location of the color filter layer.

13. The method of manufacturing a display panel according to claim 10, wherein the mask is a gray scale mask.

14. The method of manufacturing a display panel according to claim 13, wherein the planarization layer is etched by employing the gray scale mask to form the groove structure corresponding to the location of the color filter layer.

15. The method of manufacturing a display panel according to claim 10, wherein a projection of the groove structure onto the substrate is included in a projection of the color filter layer onto the substrate.

16. The method of manufacturing a display panel according to claim 10, wherein the color filter layer includes a plurality of color resistors configured in an array, and colors of any adjacent color resistors are different.

17. The method of manufacturing a display panel according to claim 10, wherein each of the plurality of thin film transistors comprises a semiconductor layer, a source electrode, a drain electrode and a gate electrode.

18. The method of manufacturing a display panel according to claim 17, further comprising a gate insulating layer disposed between the drain electrode and the semiconductor layer.

19. The method of manufacturing a display panel according to claim 17, wherein the semiconductor layer is an indium gallium zinc oxide thin film layer.

20. A display panel, comprising:
a substrate;
a plurality of thin film transistors, arranged on the substrate;
a passivation layer, disposed on the substrate and covering the plurality of thin film transistors;
a pixel definition layer, disposed on the passivation layer and configured to enable a plurality of light emitting elements to be disposed therein;
a planarization layer, interposed between the passivation layer and the pixel definition layer, and having a groove structure;
a color filter layer, interposed between the passivation layer and the planarization layer, and aligned to a location of the groove structure of the planarization layer; and
a transparent electrode layer, disposed on the planarization layer and covering the groove structure;
wherein the plurality of light emitting elements are disposed in the groove structure of the planarization layer and is aligned to the location of the color filter layer;
wherein a projection of the groove structure onto the substrate is included in a projection of the color filter layer onto the substrate;
wherein the color filter layer includes a plurality of color resistors configured in an array, and colors of any adjacent color resistors are different;
wherein the plurality of light emitting elements are aligned to the location of the color filter layer, and each of the plurality of light emitting elements is a white light emitting diode or a colored light emitting diode.
